(19) United States
(12) Patent Application Publication
(10) Pub. No.: US 2026/0342294 A1
(43) Pub. Date: Oct. 29, 2026

(54) INTEROPERABLE TRANSMIT POWER ENVELOP (TPE) SIGNALING WITH AUTOMATED FREQUENCY COORDINATION (AFC) FREQUENCY RESPONSE

(71) Applicant: Cisco Technology, Inc., San Jose, CA (US)

(72) Inventors: Brian D. Hart, Sunnyvale, CA (US); Sachin D. Wakudkar, St-Sulpice (CH); Nedime Pelin Mohamed Hassan Salem, San Jose, CA (US)

(73) Assignee: Cisco Technology, Inc., San Jose, CA (US)

(21) Appl. No.: 19/736,887

(22) Filed: Jul. 9, 2026

Related U.S. Application Data
(63) Continuation of application No. 18/893,094, filed on Sep. 23, 2024.
(60) Provisional application No. 63/584,846, filed on Sep. 22, 2023.

(51) Int. Cl. H03F 3/24; H04W 16/14

(52) U.S. Cl. CPC H03F 3/24; H04W 16/14; H03F 2200/451

(57) ABSTRACT

Interoperable Transmit Power Envelop (TPE) signaling with Automated Frequency Coordination (AFC) frequency response may be provided. First, AFC information may be received. Next a mask may be determined for a punctured channel indicated in the AFC information. Then a first amount may be determined that the mask needs to be altered to reach an AFC response for the punctured channel indicated in the AFC information. A Transmit Power Envelop (TPE) value may then be reported for the punctured channel comprising the first amount plus a second amount.

### CROSS-REFERENCE TO RELATED APPLICATIONS

This application is a continuation of U.S. patent application Ser. No. 18/893,094, filed Sept. 23, 2024, which claims priority to and benefit of U.S. Provisional Application No. 63/584,846 filed Sept. 22, 2023, each of which are incorporated herein by reference.

### TECHNICAL FIELD

The present disclosure relates generally to providing interoperable Transmit Power Envelop (TPE) signaling with Automated Frequency Coordination (AFC) frequency response.

### BACKGROUND

In computer networking, a wireless Access Point (AP) is a networking hardware device that allows a Wi-Fi compatible client device to connect to a wired network and to other client devices. The AP usually connects to a router (directly or indirectly via a wired network) as a standalone device, but it can also be an integral component of the router itself. Several APs may also work in coordination, either through direct wired or wireless connections, or through a central system, commonly called a Wireless Local Area Network (WLAN) controller. An AP is differentiated from a hotspot, which is the physical location where Wi-Fi access to a WLAN is available.

Prior to wireless networks, setting up a computer network in a business, home, or school often required running many cables through walls and ceilings in order to deliver network access to all of the network-enabled devices in the building. With the creation of the wireless AP, network users are able to add devices that access the network with few or no cables. An AP connects to a wired network, then provides radio frequency links for other radio devices to reach that wired network. Most APs support the connection of multiple wireless devices. APs are built to support a standard for sending and receiving data using these radio frequencies.

### BRIEF DESCRIPTION OF THE FIGURES

The accompanying drawings, which are incorporated in and constitute a part of this disclosure, illustrate various embodiments of the present disclosure. In the drawings:

FIG. 1 is a block diagram of an operating environment for providing interoperable Transmit Power Envelop (TPE) signaling with Automated Frequency Coordination (AFC) frequency response;

FIG. 2 is a flow chart of a method for providing interoperable Transmit Power Envelop (TPE) signaling with Automated Frequency Coordination (AFC) frequency response;

FIG. 3 illustrates an AFC frequency response for a punctured subchannel and a mask;

FIG. 4 illustrates options for a TPE element; and

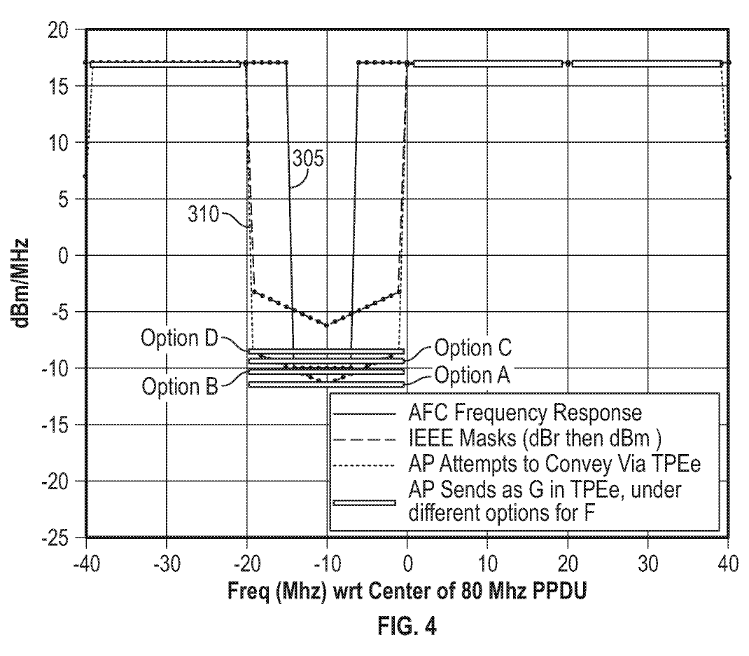

FIG. 5 is a block diagram of a computing device.

### DETAILED DESCRIPTION

### OVERVIEW

Interoperable Transmit Power Envelop (TPE) signaling with Automated Frequency Coordination (AFC) frequency response may be provided. First, AFC information may be received. Next a mask may be determined for a punctured channel indicated in the AFC information. Then a first amount may be determined that the mask needs to be altered to reach an AFC response for the punctured channel indicated in the AFC information. A Transmit Power Envelop (TPE) value may then be reported for the punctured channel comprising the first amount plus a second amount.

Both the foregoing overview and the following example embodiments are examples and explanatory only and should not be considered to restrict the disclosure’s scope, as described and claimed. Furthermore, features and/or variations may be provided in addition to those described. For example, embodiments of the disclosure may be directed to various feature combinations and sub-combinations described in the example embodiments.

### EXAMPLE EMBODIMENTS

The following detailed description refers to the accompanying drawings. Wherever possible, the same reference numbers are used in the drawings and the following description to refer to the same or similar elements. While embodiments of the disclosure may be described, modifications, adaptations, and other implementations are possible. For example, substitutions, additions, or modifications may be made to the elements illustrated in the drawings, and the methods described herein may be modified by substituting, reordering, or adding stages to the disclosed methods. Accordingly, the following detailed description does not limit the disclosure. Instead, the proper scope of the disclosure is defined by the appended claims.

Embodiments of the disclosure may transfer the Automated Frequency Coordination (AFC) frequency response to clients and enable them to use as much power as possible while still using the Transmit Power Envelop (TPE) element for backwards compatibility. An AP may get a frequency response from AFC. A channel response from the AFC may be ignored because the solution for puncturing via the frequency response may be clearer. For a punctured channel, the AP/fixed client may know their own Transmit (TX) mask versus TX power, so they may choose a TX power that meets the AFC frequency response. The AP may also need to compress the AFC frequency response to one value per 20 MHz, and the client may need to decompress that and reliably infer what the AP meant. Typically, in source compression schemes, the behavior of the recipient may be standardized. If the AP and client make different assumptions, various undesired events may occur.

Embodiments of the disclosure may allow the AP to compactly express how a complicated client TX Power Spectral Density (PSD) may rest as tightly as possible against a potentially complicated AFC frequency response. If nothing is assumed about the client TX PSD: i) client compliance may only be guaranteed if the AP reports the minimum AFC frequency response over the punctured subchannel in the TPE element field, then the client ensures its PSD may be everywhere below this minimum; and ii) in many cases the client TX PSD may not rest tightly against the AFC frequency response. Accordingly, embodiments of the disclosure may allow clients to use as close to the maximum power allowed by the AFC frequency response while maintaining the format of the TPE by defining an indirect way by which the maximum transmit PSD X fields in the TPE element sent by the AP may be interpreted by clients as sliding an Institute of Electrical and Electronics Engineers (IEEE) mask up or down over punctured channels.

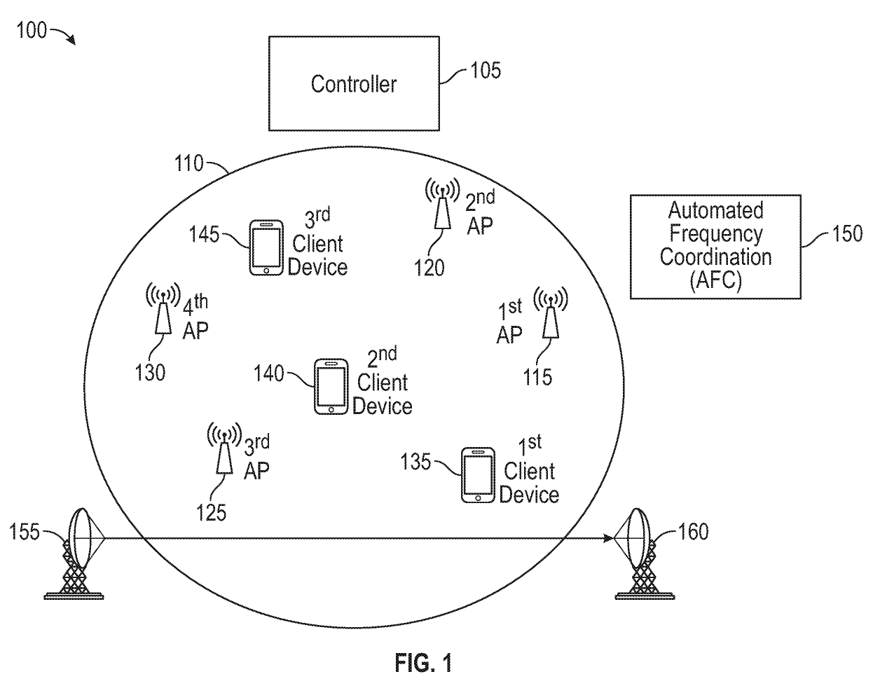

FIG. 1 shows an operating environment 100 for providing interoperable Transmit Power Envelop (TPE) signaling with Automated Frequency Coordination (AFC) frequency response. As shown in FIG. 1, operating environment 100 may comprise a controller 105 and a coverage environment 110. Coverage environment 110 may comprise, but is not limited to, a Wireless Local Area Network (WLAN) comprising a plurality of Access Points (APs) that may provide wireless network access (e.g., access to the WLAN for client devices). The plurality of APs may comprise a first AP 115, a second AP 120, a third AP 125, and a fourth AP 130. The plurality of APs may provide wireless network access to a plurality of client devices as they move within coverage environment 110. The plurality of client devices may comprise, but are not limited to, a first client device 135, a second client device 140, and a third client device 145. Ones of the plurality of client devices may comprise, but are not limited to, a smart phone, a personal computer, a tablet device, a mobile device, a telephone, a remote control device, a set-top box, a digital video recorder, an Internet-of-Things (IoT) device, a network computer, a router, Virtual Reality (VR)/Augmented Reality (AR) devices, or other similar microcomputer-based device. Each of the plurality of APs may be compatible with specification standards such as, but not limited to, the IEEE 802.11 specification standard for example.

The plurality of APs and the plurality of client devices may use Multi-Link Operation (MLO) where they simultaneously transmit and receive across different bands and channels by establishing two or more links to two or more AP radios. These bands may comprise, but are not limited the 2 GHz band, the 5 GHz band, the 6 GHz band, and the 60 GHz band.

Controller 105 may comprise a Wireless Local Area Network controller (WLC) and may provision and control coverage environment 110 (e.g., a WLAN). Controller 105 may allow first client device 135, second client device 140, and third client device 145 to join coverage environment 110. In some embodiments of the disclosure, controller 105 may be implemented by a Digital Network Architecture Center (DNAC) controller (i.e., a Software-Defined Network (SDN) controller) that may configure information for coverage environment 110 in order to provide interoperable TPE signaling with AFC frequency response.

In order for unlicensed devices (e.g., Wi-Fi devices such as client devices and APs) to work with the licensed users already occupying a band (e.g., the 6 GHz band), AFC was established. AFC is a spectrum use coordination system. For example, because the 6 GHz band was already occupied by incumbent users (i.e., Fixed Services (FS)), such as fixed satellite providers, restrictions may be placed on the Wi-Fi devices looking to transmit in this band. To avoid potential interference with existing 6 GHz incumbents, AFC may impose two types of device classifications with different transmit power rules for Wi-Fi devices operating on the band: i) low power APs for indoor Wi-Fi and ii) standard power APs that may be used indoors and outdoors.

As shown in FIG. 1, AFC 150 may provide spectrum use coordination for coverage environment 110. A transmitter 155 and a receiver 160 may comprise a licensed FS incumbent user. First AP 115, second AP 120, third AP 125, and fourth AP 130 may comprise unlicensed devices. AFC 150 may coordinate spectrum use between the licensed and unlicensed to avoid potential interference in coverage environment 110.

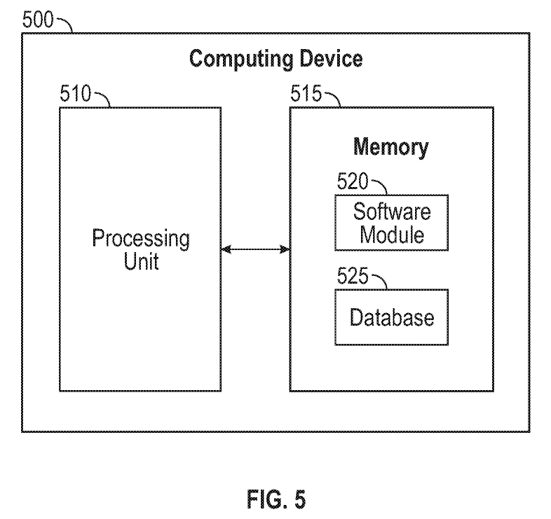

The elements described above of operating environment 100 (e.g., controller 105, first AP 115, second AP 120, third AP 125, fourth AP 130, first client device 135, second client device 140, or third client device 145) may be practiced in hardware and/or in software (including firmware, resident software, micro-code, etc.) or in any other circuits or systems. The elements of operating environment 100 may be practiced in electrical circuits comprising discrete electronic elements, packaged or integrated electronic chips containing logic gates, a circuit utilizing a microprocessor, or on a single chip containing electronic elements or microprocessors. Furthermore, the elements of operating environment 100 may also be practiced using other technologies capable of performing logical operations such as, for example, AND, OR, and NOT, including but not limited to, mechanical, optical, fluidic, and quantum technologies. As described in greater detail below with respect to FIG. 5, the elements of operating environment 100 may be practiced in a computing device 500.

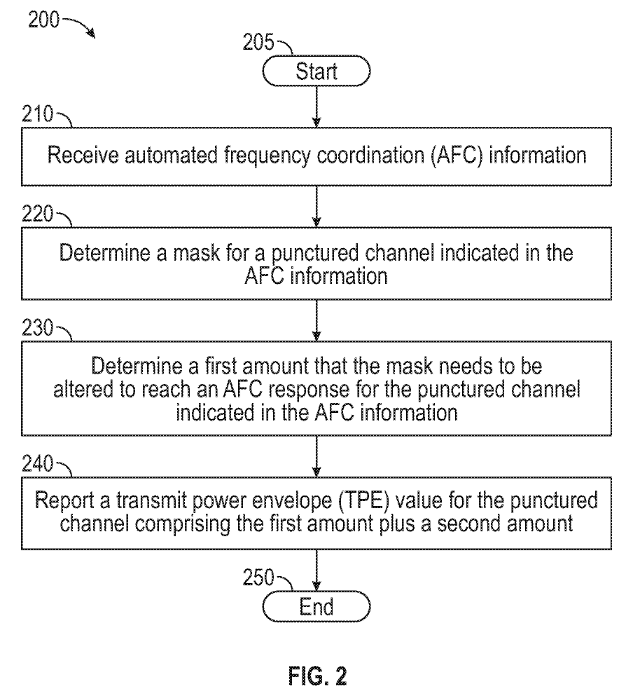

FIG. 2 is a flow chart setting forth the general stages involved in a method 200 consistent with embodiments of the disclosure for providing interoperable TPE signaling with AFC frequency response. Method 200 may be implemented using computing device 500 as described in more detail below with respect to FIG. 5. Computing device 500 may be embodied by first AP 115 for example. Ways to implement the stages of method 200 will be described in greater detail below.

Method 200 may begin at starting block 205 and proceed to stage 210 where first AP 115 may receive Automated Frequency Coordination (AFC) information. For example, the AFC information relative to operating environment 100 may be received by first AP 115 from AFC 150. The AFC information may indicate which channels should be punctured.

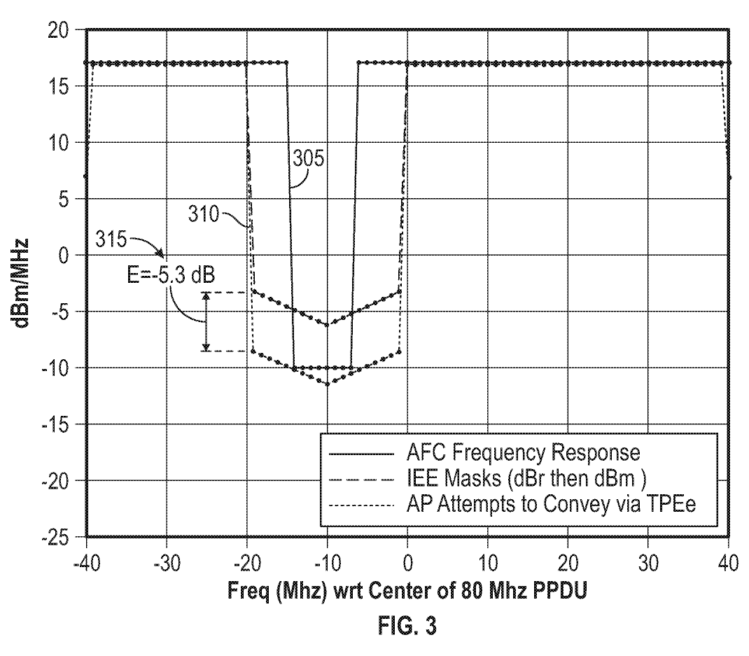

From stage 210, where first AP 115 receives the AFC information, method 200 may advance to stage 220 where first AP 115 may determine a mask for a punctured channel indicated in the AFC information. For example, for each punctured channel indicated by the AFC information, given the absolute power advertised in a TPE element for nearby unpunctured 20 MHz subchannels, AP 115 may calculate an IEEE mask in absolute power: IEEE Mask dBm (puncChCenterHz) + power In dBm (quantizedFreq), |quantizedFreq| < puncChCenterHz +10 MHz. Because AFC may operate at 1 MHz resolution, then quantizedFreq may also, and then quantizedFreq may equal puncChCenterHz - 9 MHz, puncChCenterHz -8 MHz, … puncChCenterHz +9 MHz. This may allow the avoidance of steep slopes at the edges of the punctured sub-channel. An AFC frequency response 305 for a punctured subchannel and an IEEE mask 310 are illustrated in FIG. 3.

Once first AP 115 determines the mask for the punctured channel indicated in the AFC information in stage 220, method 200 may continue to stage 230 where first AP 115 may determine a first amount 315 that mask 310 may need to be altered to reach AFC frequency response 305 for the punctured channel indicated in the AFC information. For example, first amount 315 may comprise “E” dB as the amount in dB by which the IEEE mask 310 may need to increase to reach AFC frequency response 305. E may be negative if IEEE mask 310 is too high at any point.

A client device in operating environment 100 may receive the reported TPE element and infer an approximation of the AFC frequency response in a similar way as described above. The client device may use a flat frequency response for unpunctured channels. For each punctured channel, given the absolute power advertised in the TPE element for nearby unpunctured 20 MHz subchannels, the client device may first calculate the IEEE mask in absolute power and thence F. Second, the client device may infer E = G - F, and so may slide the IEEE mask of the punctured subchannel up by E (or down by |E| if E is negative).

The client device may then pick a power for its transmissions such that its TX PSD is everywhere under the inferred AFC frequency response. Then if the client device knows its punctured mask is better (or worse) than the IEEE mask, it may transmit at a higher (or lower) power as long as its PSD is under the inferred AFC frequency response. Once first AP 115 reports the TPE value for the punctured channel comprising the first amount plus a second amount in stage 240, method 200 may then end at stage 250.

FIG. 5 shows computing device 500. As shown in FIG. 5, computing device 500 may include a processing unit 510 and a memory unit 515. Memory unit 515 may include a software module 520 and a database 525. While executing on processing unit 510, software module 520 may perform, for example, processes for providing interoperable TPE signaling with AFC frequency response as described above with respect to FIG. 2. Computing device 500, for example, may provide an operating environment for controller 105, first AP 115, second AP 120, third AP 125, first client device 130, second client device 135, or third client device 140. Controller 105, first AP 115, second AP 120, third AP 125, first client device 130, second client device 135, or third client device 140 may operate in other environments and are not limited to computing device 500.

Computing device 500 may be implemented using a Wi-Fi access point, a tablet device, a mobile device, a smart phone, a telephone, a remote control device, a set-top box, a digital video recorder, a cable modem, a personal computer, a network computer, a mainframe, a router, a switch, a server cluster, a smart TV-like device, a network storage device, a network relay device, or other similar microcomputer-based device. Computing device 500 may comprise any computer operating environment, such as hand-held devices, multiprocessor systems, microprocessor-based or programmable sender electronic devices, minicomputers, mainframe computers, and the like. Computing device 500 may also be practiced in distributed computing environments where tasks are performed by remote processing devices. The aforementioned systems and devices are examples, and computing device 500 may comprise other systems or devices.

Embodiments of the disclosure, for example, may be implemented as a computer process (method), a computing system, or as an article of manufacture, such as a computer program product or computer readable media. The computer program product may be a computer storage media readable by a computer system and encoding a computer program of instructions for executing a computer process. The computer program product may also be a propagated signal on a carrier readable by a computing system and encoding a computer program of instructions for executing a computer process. Accordingly, the present disclosure may be embodied in hardware and/or in software (including firmware, resident software, micro-code, etc.). In other words, embodiments of the present disclosure may take the form of a computer program product on a computer-usable or computer-readable storage medium having computer-usable or computer-readable program code embodied in the medium for use by or in connection with an instruction execution system. A computer-usable or computer-readable medium may be any medium that can contain, store, communicate, propagate, or transport the program for use by or in connection with the instruction execution system, apparatus, or device.

The computer-usable or computer-readable medium may be, for example but not limited to, an electronic, magnetic, optical, electromagnetic, infrared, or semiconductor system, apparatus, device, or propagation medium. More specific computer-readable medium examples (a non-exhaustive list), the computer-readable medium may include the following: an electrical connection having one or more wires, a portable computer diskette, a random access memory (RAM), a read-only memory (ROM), an erasable programmable read-only memory (EPROM or Flash memory), an optical fiber, and a portable compact disc read-only memory (CD-ROM). Note that the computer-usable or computer-readable medium could even be paper or another suitable medium upon which the program is printed, as the program can be electronically captured, via, for instance, optical scanning of the paper or other medium, then compiled, interpreted, or otherwise processed in a suitable manner, if necessary, and then stored in a computer memory.

While certain embodiments of the disclosure have been described, other embodiments may exist. Furthermore, although embodiments of the present disclosure have been described as being associated with data stored in memory and other storage mediums, data can also be stored on or read from other types of computer-readable media, such as secondary storage devices, like hard disks, floppy disks, or a CD-ROM, a carrier wave from the Internet, or other forms of RAM or ROM. Further, the disclosed methods’ stages may be modified in any manner, including by reordering stages and/or inserting or deleting stages, without departing from the disclosure.

Furthermore, embodiments of the disclosure may be practiced in an electrical circuit comprising discrete electronic elements, packaged or integrated electronic chips containing logic gates, a circuit utilizing a microprocessor, or on a single chip containing electronic elements or microprocessors. Embodiments of the disclosure may also be practiced using other technologies capable of performing logical operations such as, for example, AND, OR, and NOT, including but not limited to, mechanical, optical, fluidic, and quantum technologies. In addition, embodiments of the disclosure may be practiced within a general purpose computer or in any other circuits or systems.

Embodiments of the disclosure may be practiced via a system-on-a-chip (SOC) where each or many of the element illustrated in FIG. 1 may be integrated onto a single integrated circuit. Such an SOC device may include one or more processing units, graphics units, communications units, system virtualization units and various application functionality all of which may be integrated (or “burned”) onto the chip substrate as a single integrated circuit. When operating via an SOC, the functionality described herein with respect to embodiments of the disclosure, may be performed via application-specific logic integrated with other components of computing device 500 on the single integrated circuit (chip).

Embodiments of the present disclosure, for example, are described above with reference to block diagrams and/or operational illustrations of methods, systems, and computer program products according to embodiments of the disclosure. The functions/acts noted in the blocks may occur out of the order as shown in any flowchart. For example, two blocks shown in succession may in fact be executed substantially concurrently or the blocks may sometimes be executed in the reverse order, depending upon the functionality/acts involved.

While the specification includes examples, the disclosure’s scope is indicated by the following claims. Furthermore, while the specification has been described in language specific to structural features and/or methodological acts, the claims are not limited to the features or acts described above. Rather, the specific features and acts described above are disclosed as example for embodiments of the disclosure.

What is claimed is:

1. A method comprising:
providing, by an access point, wireless network access to one or more client devices on an operating channel;
accessing, by the access point, spectrum use coordination information from an external system, the spectrum use coordination information defining a frequency response at a first frequency resolution finer than a subchannel bandwidth;
determining, by the access point, a mask for a punctured subchannel indicated in the spectrum use coordination information, wherein the mask is configured to comply with the frequency response for the punctured subchannel indicated in the spectrum use coordination information; and
reporting, by the access point, a Transmit Power Envelope (TPE) value for the punctured subchannel, wherein the TPE value for the punctured subchannel is no greater than a lowest allowed transmit power spectral density (PSD) value in the mask for the punctured subchannel.

2. The method of claim 1 wherein the TPE value for the punctured subchannel is a maximum value no greater than the lowest allowed transmit power spectral density (PSD) value in the mask for the punctured subchannel.

3. The method of claim 1 wherein the one or more client devices infer the frequency response indicated in the spectrum use coordination information from the TPE value for the punctured subchannel; and
compute transmit powers for transmissions on the operating channel such that transmit PSD is lower than inferred frequency response at all frequencies within the punctured subchannel, wherein the transmit PSD varies from the TPE value across the frequency spectrum within the punctured subchannel.

4. The method of claim 3 wherein the transmit PSD is higher than the TPE value at frequencies proximal to edges of the punctured subchannel.

5. The method of claim 1 wherein the spectrum use coordination information comprises Automated Frequency Coordination (AFC) information.

6. The method of claim 1 wherein the spectrum use coordination information comprises spectrum use coordination information governing use of a frequency band between licensed and unlicensed users.

7. The method of claim 1 wherein the TPE value is contained in a TPE element.

8. The method of claim 7 wherein the TPE element comprises additional TPE values for non-punctured subchannels of the operating channel.

9. An access point comprising:
at least one memory element for storing data; and
at least one processor for executing instructions associated with the data, wherein executing the instructions causes the access point to perform operations, comprising:
providing wireless network access to one or more client devices on an operating channel;
accessing spectrum use coordination information from an external system, the spectrum use coordination information defining a frequency response at a first frequency resolution finer than a subchannel bandwidth;
determining a mask for a punctured subchannel indicated in the spectrum use coordination information, wherein the mask is configured to comply with the frequency response for the punctured subchannel indicated in the spectrum use coordination information; and
reporting a Transmit Power Envelope (TPE) value for the punctured subchannel, wherein the TPE value for the punctured subchannel is no greater than a lowest allowed transmit power spectral density (PSD) value in the mask for the punctured subchannel.

10. The access point of claim 9 wherein the TPE value for the punctured subchannel is a maximum value no greater than the lowest allowed transmit power spectral density (PSD) value in the mask for the punctured subchannel.

11. The access point of claim 9 wherein the one or more client devices infer the frequency response indicated in the spectrum use coordination information from the TPE value for the punctured subchannel; and
compute transmit powers for transmissions on the operating channel such that transmit PSD is lower than inferred frequency response at all frequencies within the punctured subchannel, wherein the transmit PSD varies from the TPE value across the frequency spectrum within the punctured subchannel.

12. The access point of claim 11 wherein the transmit PSD is higher than the TPE value at frequencies proximal to edges of the punctured subchannel.

13. The access point of claim 9 wherein the spectrum use coordination information comprises Automated Frequency Coordination (AFC) information.

14. The access point of claim 9 wherein the spectrum use coordination information comprises spectrum use coordination information governing use of a frequency band between licensed and unlicensed users.

15. The access point of claim 9 wherein the TPE value is contained in a TPE element.

16. The access point of claim 15 wherein the TPE element comprises additional TPE values for non-punctured subchannels of the operating channel.

17. A non-transitory computer readable storage medium comprising instructions that when executed configure one or more processors of an access point to perform operations comprising:
providing wireless network access to one or more client devices on an operating channel;
accessing spectrum use coordination information from an external system, the spectrum use coordination information defining a frequency response at a first frequency resolution finer than a subchannel bandwidth;
determining a mask for a punctured subchannel indicated in the spectrum use coordination information, wherein the mask is configured to comply with the frequency response for the punctured subchannel indicated in the spectrum use coordination information; and
reporting a Transmit Power Envelope (TPE) value for the punctured subchannel, wherein the TPE value for the punctured subchannel is no greater than a lowest allowed transmit power spectral density (PSD) value in the mask for the punctured subchannel.

18. The non-transitory computer readable storage medium of claim 17 wherein the TPE value for the punctured subchannel is a maximum value no greater than the lowest allowed transmit power spectral density (PSD) value in the mask for the punctured subchannel.

19. The non-transitory computer readable storage medium of claim 17 wherein the one or more client devices infer the frequency response indicated in the spectrum use coordination information from the TPE value for the punctured subchannel; and
compute transmit powers for transmissions on the operating channel such that transmit PSD is lower than inferred frequency response at all frequencies within the punctured subchannel, wherein the transmit PSD varies from the TPE value across the frequency spectrum within the punctured subchannel.

20. The non-transitory computer readable storage medium of claim 19 wherein the transmit PSD is higher than the TPE value at frequencies proximal to edges of the punctured subchannel.

21. The non-transitory computer readable storage medium of claim 17 wherein the spectrum use coordination information comprises Automated Frequency Coordination (AFC) information.

22. The non-transitory computer readable storage medium of claim 17 wherein the spectrum use coordination information comprises spectrum use coordination information governing use of a frequency band between licensed and unlicensed users.

23. The non-transitory computer readable storage medium of claim 17 wherein the TPE value is contained in a TPE element.

24. The non-transitory computer readable storage medium of claim 23 wherein the TPE element comprises additional TPE values for non-punctured subchannels of the operating channel.
